(19) United States
(12) Patent Application Publication
(10) Pub. No.: US 2024/0315081 A1
(43) Pub. Date: Sep. 19, 2024

(54) DISPLAY PANEL

(71) Applicant: Shenzhen China Star Optoelectronics Semiconductor Display Technology Co., Ltd., Shenzhen (CN)

(72) Inventor: Huan LUO, Shenzhen (CN)

(73) Assignee: Shenzhen China Star Optoelectronics Semiconductor Display Technology Co., Ltd., Shenzhen (CN)

(21) Appl. No.: 18/398,249

(22) Filed: Dec. 28, 2023

(30) Foreign Application Priority Data
Mar. 13, 2023 (CN) 202310288588.4

(51) Int. Cl. H10K 59/122; H10K 59/80

(52) U.S. Cl. CPC H10K 59/122; H10K 59/8792

(57) ABSTRACT

The present application provides a display panel including an array substrate, a pixel definition layer, and a color film layer. The pixel definition layer is disposed on the array substrate. The color film layer is disposed on a side of the pixel definition layer away from the array substrate and includes a light shielding layer. At least one surface of the light shielding layer in the thickness direction of the light shielding layer is provided with a first concave-convex structure.

This application claims the benefit priority of Chinese Patent Application No. 202310288588.4, filed on Mar. 13, 2023, the contents of which are incorporated by reference as if fully set forth herein in their entirety.

### TECHNICAL FIELD

The present application relates to the field of display technologies, and especially relates to a display panel.

### BACKGROUND

In the field of display technologies, due to organic light emitting diode (OLED) display devices response faster than liquid crystal display devices and have advantages such as bright color, light weight and the like, the organic light emitting diode display devices have become mainstream technology of the next generation display. However, the organic light emitting diode display devices have a problem of low contrast, which affects display effect thereof.

Therefore, it is necessary to propose a technical solution to improve contrast of the organic light emitting diode display devices, thereby improving display effect thereof.

### SUMMARY

An object of the present application is to provide a display panel to improve contrast in a case that the display panel displays.

To achieve the above purpose, the technical solution is as follows.

A display panel, including:
an array substrate;
a pixel definition layer disposed on the array substrate; and
a color film layer disposed on a side of the pixel definition layer away from the array substrate, the color film layer includes a light shielding layer, and at least one surface of the light shielding layer in a thickness direction of the light shielding layer is provided with a first concave-convex structure.

Embodiments of the present application provide a display panel, at least one surface of the light shielding layer in the thickness direction of the light shielding layer is provided with the first concave-convex structure. The first concave-convex structure diffusely reflects ambient light incident on the display panel, thereby reducing specular reflection. Moreover, the first concave-convex structure increases absorption of ambient light by the light shielding layer and reduces reflectivity of ambient light on the display panel. Thus, contrast of the display panel is further increased, thereby improving display effect of the display panel.

### BRIEF DESCRIPTION OF THE DRAWINGS

FIG. 1 is a schematic cross-sectional view of a display panel according to an embodiment of the present application.

FIG. 2 is a schematic partial plan view of a light shielding layer shown in FIG. 1.

FIG. 3 is a schematic cross-sectional view of a display panel according to another embodiment of the present application.

FIG. 4 is a partial plan view of a pixel definition layer in the display panel shown in FIG. 3.

FIG. 5 is a schematic cross-sectional view of a display panel according to another embodiment of the present application.

Reference numbers in each drawing are as follows:
100, display panel;
10, array substrate; 101, substrate; 102, array layer;
20, pixel definition layer; 201, pixel opening; 202, bank; 203, second concave-convex structure; 204, second groove;
30, color film layer; 301, light shielding layer; 3011, light shielding opening; 3012, light shielding matrix; 3013, first concave-convex structure; 3014, first groove; 302, color resistance unit;
40, light emitting unit; 401, anode; 402, organic light emitting layer; 403, cathode;
50, encapsulation substrate.

### DETAILED DESCRIPTION OF THE EMBODIMENT

The technical solutions in the embodiments of the present application are clearly and completely described below in conjunction with the drawings in the embodiments of the present application. Obviously, the embodiments described are only a part of the embodiments of the present application, rather than all the embodiments. Based on the embodiments in the present application, all other embodiments obtained by those skilled in the art without creative works should be deemed as falling within the claims of the present application.

The present application includes a display panel. The display panel includes an array substrate, a pixel definition layer, and a color film layer. The pixel definition layer is disposed on the array substrate. The color film layer is disposed on a side of the pixel definition layer away from the array substrate. The color film layer includes a light shielding layer. At least one surface of the light shielding layer in a thickness direction of the light shielding layer is provided with a first concave-convex structure.

In some embodiments, the pixel definition layer includes a black material. A surface of the pixel definition layer adjacent to the color film layer is provided with a second concave-convex structure.

In some embodiments, a shape of the first concave-convex structure is different from a shape of the second concave-convex structure.

In some embodiments, the first concave-convex structure is disposed on a surface of the light shielding layer adjacent to the pixel definition layer.

In some embodiments, the pixel definition layer is in contact with the light shielding layer, and at least a part of the first concave-convex structure and at least a part of the second concave-convex structure are in contact with and engage with each other.

In some embodiments, the display panel further includes an encapsulation substrate disposed opposite to the array substrate and disposed on a side of the color film layer away from the array substrate. The color film layer is in contact with a surface of the encapsulation substrate adjacent to the array substrate.

In some embodiments, a surface of the light shielding layer in contact with the encapsulation substrate is flat.

In some embodiments, the light shielding layer is provided with a light shielding opening. The color film layer further includes a color resistance unit disposed in the light shielding opening. The pixel definition layer is further provided with a pixel opening. The display panel further includes a light emitting unit, at least a portion of the light emitting unit is disposed in the pixel opening.

In some embodiments, the minimum value of an opening area of the light shielding opening is greater than the maximum value of an opening area of the pixel opening.

In some embodiments, the light shielding layer includes a plurality of first grooves disposed at intervals. The plurality of first grooves are recessed from a surface of the light shielding layer adjacent to the pixel definition layer to a surface of the light shielding layer away from the pixel definition layer. The depths of the plurality of first grooves are less than the thickness of the light shielding layer. The first grooves includes a concave portion of the first concave-convex structure, and portions of the light shielding layer between the plurality of first grooves disposed at intervals includes a convex portion of the first concave-convex structure.

Technical solutions of the present application are described in detail in connection with specific embodiments below.

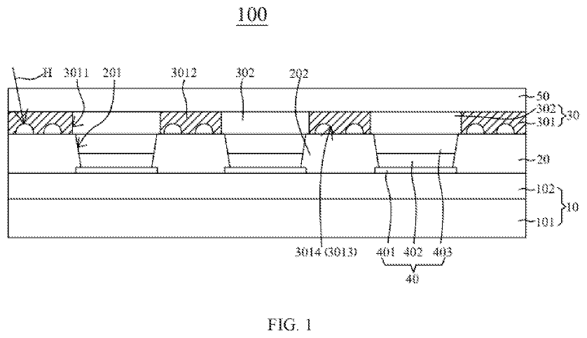

Please refer to FIG. 1, FIG. 1 is a schematic cross-sectional view of a display panel according to an embodiment of the present application. The display panel 100 includes an array substrate 10, a pixel definition layer 20, a color filter layer 30, a light emitting unit 40, and an encapsulation substrate 50.

In this embodiment, the array substrate 10 includes a substrate 101 and an array layer 102. The array layer 102 is disposed on the substrate 101. The substrate 101 is a glass substrate, but is not limited thereto. The substrate 101 may also be a flexible substrate. The array layer 102 includes a plurality of driving circuit units (not shown). Each driving circuit unit includes at least one thin film transistor.

In this embodiment, the pixel definition layer 20 is disposed on the array substrate 10. The pixel definition layer 20 includes a pixel opening 201 and a bank 202. The pixel opening 201 is configured to define a light-emitting area of the display panel 100. The pixel opening 201 goes through the pixel definition layer 20 along a thickness direction of the pixel definition layer 20. The bank 202 is provided around the pixel opening 201. A cross section shape of the pixel opening 201 along the thickness direction of the pixel definition layer 20 is an inverted trapezoid.

A color of the pixel definition layer 20 is transparent or yellow. The thickness of the pixel definition layer 20 is greater than or equal to 1.5 microns and less than or equal to 2.5 microns, such as 1.8 microns, 2.0 microns, 2.2 microns or 2.5 microns. The material of the pixel definition layer 20 includes but is not limited to polyimide.

In this embodiment, at least a portion of the light emitting unit 40 is disposed in the pixel opening 201. Each light emitting unit 40 is electrically connected to the driving circuit unit, so that the driving circuit unit drives the light emitting unit 40 to emit light. The light emitting unit 40 is an organic light emitting diode, but is not limited thereto. The light emitting unit 40 may also be any one of a quantum dot light emitting diode, a sub-millimeter light emitting diode, and a micro light emitting diode.

In a case that the light emitting unit 40 is an organic light-emitting diode, the light emitting unit 40 includes an anode 401, an organic light emitting layer 402, and a cathode 403. The organic light emitting layer 402 is disposed between the anode 401 and the cathode 403. The anode 401 is disposed on a surface of the array layer 102 of the array substrate 10. The bank 202 of the pixel definition layer 20 covers an edge of the anode 401 and the array layer 102. The organic light emitting layer 402 is disposed in the pixel opening 201 and on the anode 401. The cathode 403 is disposed on a surface of the organic light emitting layer 402 away from the anode 401.

It can be understood that the light emitting unit 40 may further include at least one of a hole transporting layer and a hole injection layer disposed between the anode 401 and the organic light emitting layer 402. The light emitting unit 40 may further include at least one of an electron transporting layer and an electron injection layer between 402 disposed between the cathode 403 and the organic light emitting layer 402.

It should be noted that the organic light emitting layer 402 and a functional layer are formed in the pixel opening 201 by an inkjet printing or an evaporation process. The functional layer includes but is not limited to at least one of the hole transporting layer, the hole injection layer, the electron transporting layer, and the electron injection layer.

In this embodiment, the color filter layer 30 is disposed on a side of the pixel definition layer 20 away from the array substrate 10. The color filter layer 30 includes a light shielding layer 301 and a plurality of color resistance units 302. The light shielding layer 301 is in contact with the bank 202 of the pixel definition layer 20.

It can be understood that a thin film encapsulation layer may also be disposed between the color filter layer 30 and the pixel definition layer 20 in other embodiments. The thin film encapsulation layer includes two inorganic insulating layers and an organic insulating layer between the two inorganic insulating layers.

Wherein, the light shielding layer 301 is a black organic layer. The thickness of the light shielding layer 301 is greater than or equal to 1.5 microns and less than or equal to 3.5 microns, such as 1.8 microns, 2.5 microns, 2.8 microns, 3 microns or 3.5 microns.

The light shielding layer 301 includes a plurality of light shielding openings 3011 that are arranged at intervals and a light shielding matrix 3012. The plurality of light shielding openings 3011 goes through the light shielding layer 301 along a thickness direction of the light shielding layer 301. Remaining light shielding layer 301 includes the light shielding matrix 3012.

The minimum value of an opening area of the light shielding opening 3011 is greater than the maximum value of an opening area of the pixel opening 201, so as to avoid crosstalk between lights of different colors emitted by a plurality of light emitting units 40, and ensure light extraction rate of the lights emitted by the light emitting units 40.

The plurality of color resistance units 302 are disposed in the plurality of light shielding openings 3011 in one-to-one correspondence. A portion of each color resistance unit 302 is in contact with the bank 202 of the pixel definition layer 20. The plurality of color resistance units 302 include a red color resistor, a blue color resistor, and a green color resistor.

In this embodiment, at least one surface of the light shielding layer 301 in the thickness direction of the light shielding layer 301 is provided with a first concave-convex structure 3013. The first concave-convex structure 3013 diffusely reflects ambient light H incident on the display panel 100, thereby reducing specular reflection. Moreover, the first concave-convex structure 3013 increases absorption of ambient light H by the light shielding layer 301 and reduces reflectivity of ambient light H on the display panel 100. Thus, contrast of the display panel 100 is further increased, thereby improving display effect of the display panel 100.

Specifically, the first concave-convex structure 3013 is disposed on a surface of the light shielding layer 301 adjacent to the pixel definition layer 20, so that the first concave-convex structure 3013 can diffusely reflect ambient light H incident into the light shielding layer 301 and increase absorption of ambient light H by the light shielding layer 301.

It can be understood that the first concave-convex structure 3013 may also be disposed on a surface of the light shielding layer 301 away from the pixel definition layer 20, so that the first concave-convex structure 3013 reflects ambient light incident on the surface of the light shielding layer 301 away from the pixel definition layer 20 H.

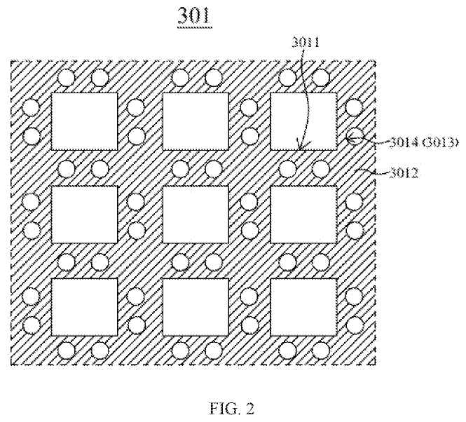

Please refer to FIG. 2, FIG. 2 is a schematic partial plan view of a light shielding layer shown in FIG. 1. The light shielding layer 301 includes a plurality of first grooves 3014 arranged at intervals. The plurality of first grooves 3014 are recessed from the surface of the light shielding layer 301 adjacent to the pixel definition layer 20 to a surface of the light shielding layer 301 away from the pixel definition layer 20. The depths of the plurality of first groove 3014 are less than the thickness of the light shielding layer 301.

The first groove 3014 includes a concave portion of the first concave-convex structure 3013, and portions of the light shielding layer 301 between the plurality of first grooves 3014 disposed at intervals includes a convex portion of the first concave-convex structure 3013.

A periphery of each light shielding opening 3011 is provided with a plurality of first grooves 3014 disposed at intervals, so that the periphery of each light shielding opening 3011 is provided with a plurality of first concave-convex structures 3013, so as to better diffusely reflect and absorb ambient light H incident on the light shielding layer 301.

A cross-sectional shape of each first groove 3014 along the direction perpendicular to the thickness of the light shielding layer 301 includes but is not limited to at least one of a rectangle, a circle, and an ellipse. A cross-sectional shape of each first groove 3014 along the thickness direction of the light shielding layer 301 includes but is not limited to at least one of semicircle, semiellipse, rectangle, triangle, trapezoid, and inverted trapezoid.

It should be noted that the first grooves 3014 are obtained by plasma process or surface etching process.

In this embodiment, the encapsulation substrate 50 and the array substrate 10 are arranged oppositely. The encapsulation substrate 50 can be connected to the array substrate 10 through a sealing frame adhesive. The encapsulation substrate 50 is a transparent glass substrate, but is not limited thereto. The encapsulation substrate 50 may also be a transparent polymer substrate.

Specifically, the encapsulation substrate 50 is disposed on a side of the color filter layer 30 away from the array substrate 10. The color filter layer 30 is in contact with a surface of the encapsulation substrate 50 adjacent to the array substrate 10. A surface of the light shielding layer 301 in contact with the encapsulation substrate 50 is flat. Thus, the encapsulation substrate 50 can be disposed flatly on the color filter layer 30, thereby ensuring flatness of the display panel 100.

It should be noted that after the color filter layer 30 is formed on the encapsulation substrate 50, the encapsulation substrate 50 provided with the color filter layer 30 is bonded to the array substrate 10 provided with the light emitting unit 40 to obtain the display panel 100.

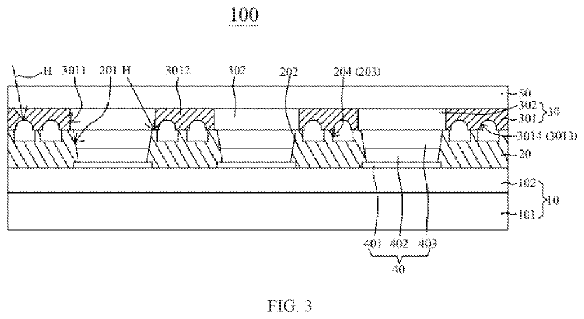

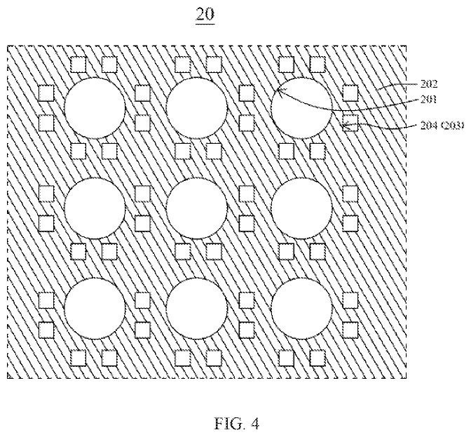

Please refer to FIGS. 3 and 4, FIG. 3 a schematic cross-sectional view of a display panel according to another embodiment of the present application, and FIG. 4 is a partial plan view of a pixel definition layer in the display panel shown in FIG. 3.

The display panel shown in FIG. 3 is basically similar to the display panel shown in FIG. 1, similarities are not repeated, differences include that the pixel definition layer 20 includes a black material, and a surface of the pixel definition layer 20 adjacent to the color filter layer 30 is provided with a second concave-convex structure 203. Thus, the pixel definition layer 20 diffusely reflect ambient light H incident on the pixel definition layer 20 from the light shielding opening 3011, and the second concave-convex structure 203 increases absorption of ambient light H by the pixel definition layer 20. The reflectivity of the display panel 100 to ambient light H is further reduced, thereby further improving contrast of the display panel 100 during display.

It should be noted that the black material includes but is not limited to carbon black. A positive photoresist layer including the black material is exposed, developed and etched to prepare the pixel definition layer 20, or, a negative photoresist layer including black material is exposed, developed and etched to prepare the pixel definition layer.

In this embodiment, a shape of the first concave-convex structure 3013 is different from a shape of the second concave-convex structure 203, so that the first concave-convex structure 3013 and the second concave-convex structure 203 irregularly diffusely reflect ambient light H, respectively, thereby further reducing the reflectivity of the display panel 100 to ambient light H.

It can be understood that the shape of the first concave-convex structure 3013 and the shape of the second concave-convex structure 203 may also be the same.

In this embodiment, the pixel definition layer 20 includes a plurality of second grooves 204 arranged at intervals. The plurality of second grooves 204 are recessed from the surface of the pixel definition layer 20 adjacent to the color filter layer 30 to a surface of the pixel definition layer 20 away from the color filter layer. The depths of the second grooves 204 are less than the thickness of the pixel definition layer 20. The second grooves 204 include a concave portion of the second concave-convex structure 203, and portions of the pixel definition layer 20 between the plurality of second grooves 204 includes a convex portion of the second concave-convex structure 203.

It should be noted that the second grooves 204 are also obtained by plasma process or surface etching process.

A periphery of each pixel opening 201 is provided with a plurality of second grooves 204 disposed at intervals. The second grooves 204 are arranged one-to-one with the first grooves 3014 to ensure that the light shielding layer 301 is flatly disposed on the pixel definition layer 20. As such, the encapsulation substrate 50 can be disposed flatly, thereby ensuring flatness of the display panel 100.

An area of a top opening of the first groove 3014 is different from an area of a top opening of the second groove 204, which facilitates a better one-to-one correspondence between the first grooves 3014 and the second grooves 204. For example, the area of the top opening of the first groove 3014 is greater than the area of the top opening of the second groove 204, or the area of the top opening of the first groove 3014 is less than the area of the top opening of the second groove 204.

It should be noted that the top opening of the first groove 3014 is an opening of the first groove 3014 adjacent to the pixel definition layer 20, and the top opening of the second groove 204 is an opening of the second groove 204 adjacent to the light shielding layer 301.

A cross-sectional shape of each second groove 204 along a direction perpendicular to the thickness of the pixel definition layer 20 includes, but is not limited to, at least one of a rectangle, a circle, and an ellipse. A cross-sectional shape of each second groove 204 along the thickness direction of the pixel definition layer 20 includes, but is not limited to, at least one of a semicircle, a semiellipse, a rectangle, a triangle, a trapezoid, and an inverted trapezoid.

In this embodiment, a shape of the first groove 3014 is different from a shape of the second groove 204, so that the shape of the first concave-convex structure 3013 is different from the shape of the second concave-convex structure 203. For example, the first groove 3014 has a shape of hemisphere, and the second groove 204 has a shape of square frustum, but is not limited thereto.

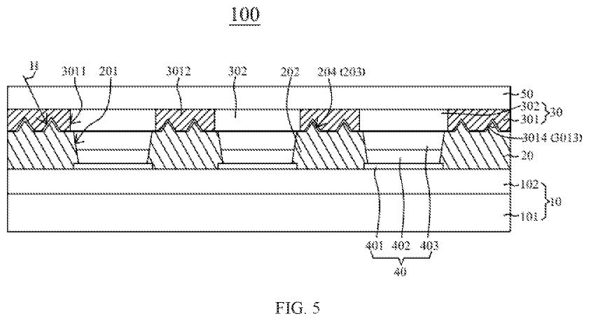

Please refer to FIG. 5, FIG. 5 is a schematic cross-sectional view of a display panel according to another embodiment of the present application. The display panel shown in FIG. 5 is basically similar to the display panel shown in FIG. 3, similarities are not described again, and differences include that at least a part of the first concave-convex structure 3013 and at least a part of the second concave-convex structure 203 are in contact with and engage with each other. Thus, the light shielding layer 301 is disposed flatly on the pixel definition layer 20, gaps defined between the pixel definition layer 20 and the light shielding layer 301 are reduced, thereby reducing a risk of side light leakage caused by lights emitted by the light emitting unit 40 leaking from the gaps.

Specifically, the first concave-convex structure 3013 and the second concave-convex structure 203 are in contact with and engaged with each other, so that the light shielding layer 301 is flatly disposed on the pixel definition layer 20, the gaps between the pixel definition layer 20 and the light shielding layer 301 are reduced, thereby reducing the risk of side light leakage caused by lights emitted by the light emitting unit 40 leaking from the gaps.

In this embodiment, the concave portion of the first concave-convex structure 3013 is engaged with the convex portion of the second concave-convex structure 203, and the convex portion of the first concave-convex structure 3013 is engaged with the concave portion of the second concave-convex structure 203.

It should be noted that the first concave-convex structure 3013 is obtained by forming the first grooves 3014 on the light shielding layer 301. The first grooves 3014 is the concave portion of the first concave-convex structure 3013, and the portion of the light shielding layer 301 between the first grooves 3014 and protruding from the first grooves 3014 is the convex portion of the first concave-convex structure 3013. In addition, the second concave-convex structure 203 is obtained by forming the second grooves 204 on the pixel definition layer 20, the second grooves 204 is the concave portion of the second concave-convex structure 203, and the portion of the pixel definition layer 20 between the plurality of second grooves 204 and protruding from the second grooves 204 is the convex portion of the second concave-convex structure 203.

For example, the concave portion of the first concave-convex structure 3013 has a shape of triangular pyramid, and the convex portion of the second concave-convex structure 203 also has a shape of triangular pyramid. It can be understood that the first concave-convex structure 3013 and the second concave-convex structure 203 can also be in a shape of a zigzag or a bank.

The descriptions of the above-mentioned embodiments are only used to help understand the technical solutions and core ideas of the present application. Those of ordinary skill in the art should understand that they can still modify the technical solutions described in the foregoing embodiments, or equivalently replace some of the technical features; and these modifications or replacements do not cause the essence of the corresponding technical solutions to deviate from the scope of the technical solutions of the embodiments of the present application.

What is claimed is:

1. A display panel, comprising:
an array substrate;
a pixel definition layer disposed on the array substrate; and
a color film layer disposed on a side of the pixel definition layer away from the array substrate, wherein the color film layer comprises a light shielding layer, and at least one surface of the light shielding layer in a thickness direction of the light shielding layer is provided with a first concave-convex structure.

2. The display panel according to claim 1, wherein the pixel definition layer comprises a black material, and a surface of the pixel definition layer adjacent to the color film layer is provided with a second concave-convex structure.

3. The display panel according to claim 2, wherein a shape of the first concave-convex structure is different from a shape of the second concave-convex structure.

4. The display panel according to claim 2, wherein the first concave-convex structure is disposed on a surface of the light shielding layer adjacent to the pixel definition layer.

5. The display panel according to claim 4, wherein the pixel definition layer is in contact with the light shielding layer, and at least a part of the first concave-convex structure and at least a part of the second concave-convex structure are in contact with and engage with each other.

6. The display panel according to claim 1, further comprising:
an encapsulation substrate disposed opposite to the array substrate and disposed on a side of the color film layer away from the array substrate, wherein the color film layer is in contact with a surface of the encapsulation substrate adjacent to the array substrate.

7. The display panel according to claim 6, wherein a surface of the light shielding layer in contact with the encapsulation substrate is flat.

8. The display panel according to claim 1, wherein the light shielding layer is provided with a light shielding opening, and the color film layer further comprises a color resistance unit disposed in the light shielding opening; and
wherein the pixel definition layer is further provided with a pixel opening, and the display panel further comprises a light emitting unit, at least a portion of the light emitting unit is disposed in the pixel opening.

9. The display panel according to claim 8, wherein the minimum value of an opening area of the light shielding opening is greater than the maximum value of an opening area of the pixel opening.

10. The display panel according to claim 1, wherein the light shielding layer comprises a plurality of first grooves disposed at intervals, and the plurality of first grooves are recessed from a surface of the light shielding layer adjacent to the pixel definition layer to a surface of the light shielding layer away from the pixel definition layer; the depths of the plurality of first grooves are less than the thickness of the light shielding layer; the first grooves comprises a concave portion of the first concave-convex structure, and portions of the light shielding layer between the plurality of first grooves disposed at intervals comprises a convex portion of the first concave-convex structure.

11. A display panel, comprising:
an array substrate;
a pixel definition layer disposed on the array substrate and comprising a bank; and
a color film layer disposed on a side of the pixel definition layer away from the array substrate, wherein the color film layer comprises a light shielding layer provided with a light shielding opening and a color resistance unit disposed in the light shielding opening, a portion of the color resistance unit is in contact with the bank, and at least one surface of the light shielding layer in a thickness direction of the light shielding layer is provided with a first concave-convex structure.

12. The display panel according to claim 11, wherein the pixel definition layer comprises a black material, and a surface of the pixel definition layer adjacent to the color film layer is provided with a second concave-convex structure.

13. The display panel according to claim 12, wherein a shape of the first concave-convex structure is different from a shape of the second concave-convex structure.

14. The display panel according to claim 12, wherein the first concave-convex structure is disposed on a surface of the light shielding layer adjacent to the pixel definition layer.

15. The display panel according to claim 14, wherein the pixel definition layer is in contact with the light shielding layer, and at least a part of the first concave-convex structure and at least a part of the second concave-convex structure are in contact with and engage with each other.

16. The display panel according to claim 11, further comprising:
an encapsulation substrate disposed opposite to the array substrate and disposed on a side of the color film layer away from the array substrate, wherein the color film layer is in contact with a surface of the encapsulation substrate adjacent to the array substrate.

17. The display panel according to claim 16, wherein a surface of the light shielding layer in contact with the encapsulation substrate is flat.

18. The display panel according to claim 11, wherein the pixel definition layer is further provided with a pixel opening, and the display panel further comprises a light emitting unit, at least a portion of the light emitting unit is disposed in the pixel opening.

19. The display panel according to claim 18, wherein the minimum value of an opening area of the light shielding opening is greater than the maximum value of an opening area of the pixel opening.

20. The display panel according to claim 11, wherein the light shielding layer comprises a plurality of first grooves disposed at intervals, and the plurality of first grooves are recessed from a surface of the light shielding layer adjacent to the pixel definition layer to a surface of the light shielding layer away from the pixel definition layer; the depths of the plurality of first grooves are less than the thickness of the light shielding layer; the first grooves comprises a concave portion of the first concave-convex structure, and portions of the light shielding layer between the plurality of first grooves disposed at intervals comprises a convex portion of the first concave-convex structure.
